(19) United States
(12) Patent Application Publication
(10) Pub. No.: US 2011/0102982 A1
(43) Pub. Date: May 5, 2011

(54) ELECTRONIC APPARATUS

(75) Inventors: Hiroyuki Minaguchi, Higashimatsuyama-shi (JP); Yuichi Hirai, Ome-shi (JP); Takayuki Arisaka, Fussa-shi (JP); Yasuyuki Suzuki, Tachikawa-shi (JP)

(73) Assignee: Kabushiki Kaisha Toshiba, Tokyo (JP)

(21) Appl. No.: 12/878,928

(22) Filed: Sep. 9, 2010

(30) Foreign Application Priority Data
Oct. 30, 2009 (JP) JP2009251172

(51) Int. Cl. H05K 7/00

(52) U.S. Cl. 361/679.01

(57) ABSTRACT

According to one embodiment, an electronic apparatus includes a main unit, a display unit, a first hinge, a second hinge, and a second frictional portion. The first hinge pivotably attaches the display unit to the main unit and includes a brake. The second hinge pivotably attaches the display unit to the main unit, is configured to rotate among a first angle at which the display unit is laid on the main unit, a second angle larger the first angle, and a third angle larger than the second angle, and includes a rotating body including a first frictional portion. The second frictional portion is configured to face a surface of the rotating body away from the first frictional portion between the first angle and the second angle, and to contact with the first frictional portion and to generate a frictional force between the second angle and the third angle.

### CROSS-REFERENCE TO RELATED APPLICATION

This application is based upon and claims the benefit of priority from Japanese Patent Application No. 2009-251172, filed Oct. 30, 2009; the entire contents of which are incorporated herein by reference.

### FIELD

Embodiments described herein relate generally to an electronic apparatus comprising hinges.

### BACKGROUND

Electronic apparatuses, such as notebook PCs, include a pair of hinges that pivotably connects a display unit to a main unit. The hinge has a brake function in order to hold the display unit at an arbitrary open angle. That is, the hinge is provided with a brake portion including, for example, a disc spring, and a predetermined torque (brake torque) acts on the hinge all the time.

Jpn. Pat. Appln. KOKAI Publication No. 7-66571 discloses an electronic apparatus comprising first and second hinges. The torque of the first hinge is constant all the time. Torque acts on the second hinge only in one direction.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view illustrating an electronic apparatus according to an embodiment of the invention;

FIG. 2 is an exemplary plan view illustrating the electronic apparatus shown in FIG. 1;

FIG. 3 is an exemplary side view illustrating the electronic apparatus shown in FIG. 1;

FIG. 4 is an exemplary cross-sectional view illustrating the electronic apparatus taken along the line F4-F4 of FIG. 2;

FIG. 5 is an exemplary exploded perspective view illustrating a brake mechanism shown in FIG. 4;

FIG. 6 is an exemplary cross-sectional view illustrating the electronic apparatus taken along the line F6-F6 of FIG. 2;

FIG. 7 is an exemplary cross-sectional view illustrating the electronic apparatus taken along the line F7-F7 of FIG. 6;

FIG. 8 is an exemplary side view schematically illustrating the movement of a first frictional portion shown in FIG. 7;

FIG. 9 is an exemplary cross-sectional view illustrating the electronic apparatus shown in FIG. 1;

FIG. 10 is an exemplary cross-sectional view illustrating the electronic apparatus shown in FIG. 1;

FIG. 11 is an exemplary diagram illustrating a torque curve of the electronic apparatus shown in FIG. 1;

FIG. 12 is an exemplary cross-sectional view illustrating a first modification of the electronic apparatus shown in FIG. 1;

FIG. 13 is an exemplary cross-sectional view illustrating a second modification of the electronic apparatus shown in FIG. 1;

FIG. 14 is an exemplary cross-sectional view illustrating a third modification of the electronic apparatus shown in FIG. 1;

FIG. 15 is an exemplary cross-sectional view illustrating a fourth modification of the electronic apparatus shown in FIG. 1; and

FIG. 16 is an exemplary diagram illustrating a torque curve of a fifth modification of the electronic apparatus shown in FIG. 1.

### DETAILED DESCRIPTION

Various embodiments will be described hereinafter with reference to the accompanying drawings. In general, according to one embodiment, an electronic apparatus comprises a main unit, a display unit, a first hinge, a second hinge, and a second frictional portion. The first hinge pivotably attaches the display unit to the main unit and comprises a brake. The second hinge pivotably attaches the display unit to the main unit, is configured to rotate among a first angle at which the display unit is laid on the main unit, a second angle larger the first angle, and a third angle larger than the second angle, and comprises a rotating body comprising a first frictional portion. The second frictional portion is configured to face a surface of the rotating body away from the first frictional portion between the first angle and the second angle, and to contact with the first frictional portion and to generate a frictional force between the second angle and the third angle.

Hereinafter, an embodiment of the invention applied to a notebook PC will be described with reference to the accompanying drawings.

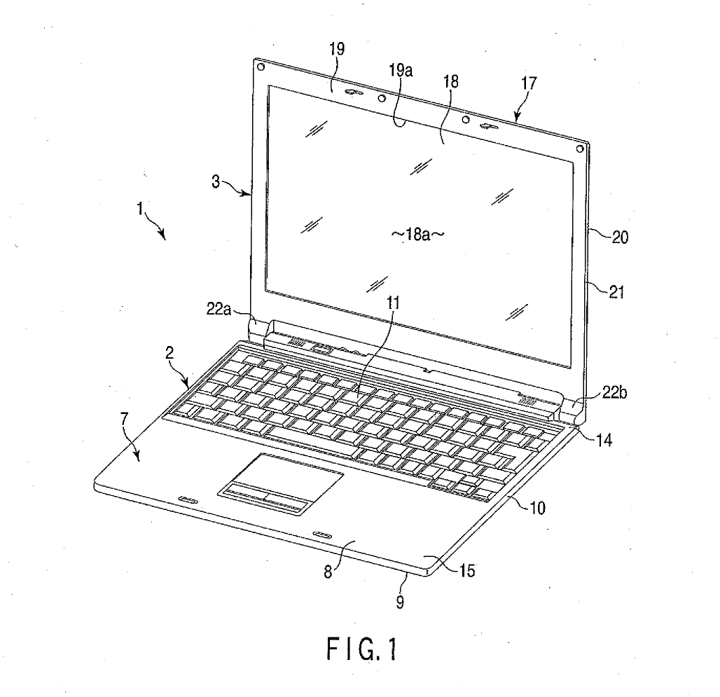

FIGS. 1 to 11 show an electronic apparatus 1 according to an embodiment of the invention. The electronic apparatus 1 is, for example, a notebook PC. However, electronic apparatuses to which the invention can be applied are not limited thereto. The invention can be widely applied to various kinds of electronic apparatuses, such as a PDA (Personal Digital Assistant) and a game machine.

As shown in FIGS. 1 to 3, the electronic apparatus 1 comprises a main unit 2, a display unit 3, and first and second hinges 4 and 5. The main unit 2 is an electronic apparatus main body provided with a main circuit board. The main unit 2 comprises a first housing 7. The first housing 7 is an example of a “housing”. The first housing 7 has a flat box shape comprising an upper wall 8, a lower wall 9, and a circumferential wall 10.

The lower wall 9 faces a desk surface when the electronic apparatus 1 is placed on a desk. The lower wall 9 is substantially parallel to the desk surface. The upper wall 8 is opposite to the lower wall 9 with a space therebetween and extends substantially in parallel (that is, substantially horizontal) to the lower wall 9. A keyboard 11 is provided on the upper wall 8. The circumferential wall 10 rises with respect to the lower wall 9, and connects the edge portion of the lower wall 9 and the edge portion of the upper wall 8.

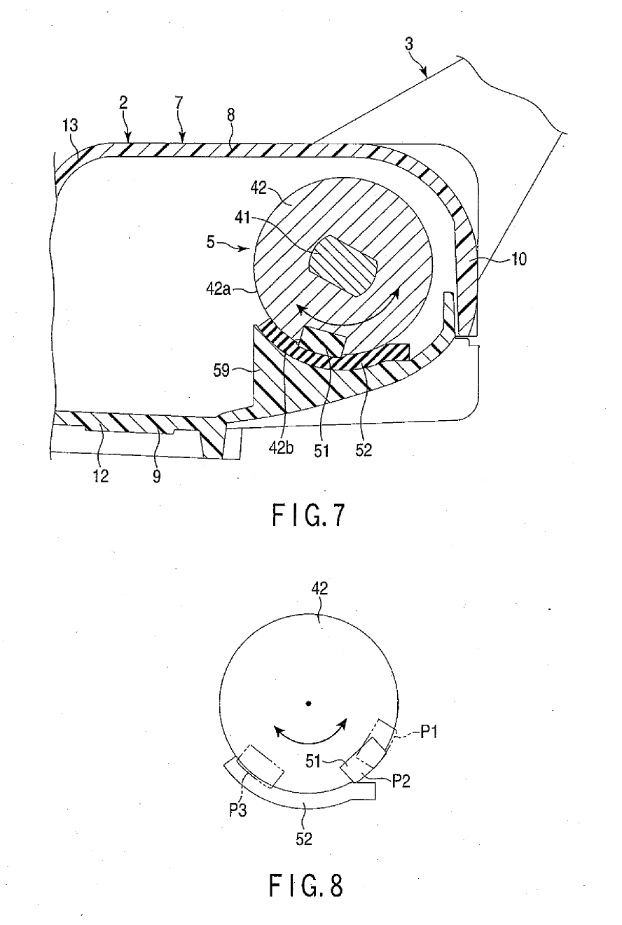

As shown in FIG. 7, the first housing 7 comprises a base member 12 (housing base) and a cover member 13 (housing cover). The base member 12 includes the lower wall 9 and a portion of the circumferential wall 10. The cover member 13 includes the upper wall 8 and a portion of the circumferential wall 10. The cover member 13 is coupled to the base member 12 to form the first housing 7.

As shown in FIG. 1, the main unit 2 comprises a rear end portion 14, which is a first end portion, and a front end 15 portion, which is a second end portion. The display unit 3 is pivotable (openably) connected to the rear end portion 14 by, for example, the first and second hinges 4 and 5. The front end portion 15 is opposite to the rear end portion 14 in the main unit 2. In the specification, the side closer to the user is defined as the front side and the side away from the user is defined as the rear side. In addition, the left and right sides are defined in the user's viewing direction.

As shown in FIG. 1, the display unit 3 comprises a second housing 17 and a display device 18 accommodated in the second housing 17. The second housing 17 has a flat box shape comprising a front wall 19, a rear wall 20, and a circumferential wall 21. In the specification, the front and rear sides are defined with respect to the raised position of the display unit 3. The second housing 17 comprises a pair of projections 22a and 22b respectively attached to the first and second hinges 4 and 5.

When the display unit 3 falls (is closed), the front wall 19 faces the upper wall 8 of the main unit 2. When the display unit 3 rises (is opened), the front wall 19 faces the user. The front wall 19 comprises a relatively large opening 19a through which a display screen 18a of the display device 18 is exposed to the outside.

The rear wall 20 is disposed opposite to the front wall 19 in the second housing 17. A space is provided between the rear wall 20 and the front wall 19, and the rear wall 20 extends substantially in parallel to the front wall 19. The circumferential wall 21 rises with respect to the rear wall 20, and connects the edge portion of the front wall 19 and the edge portion of the rear wall 20.

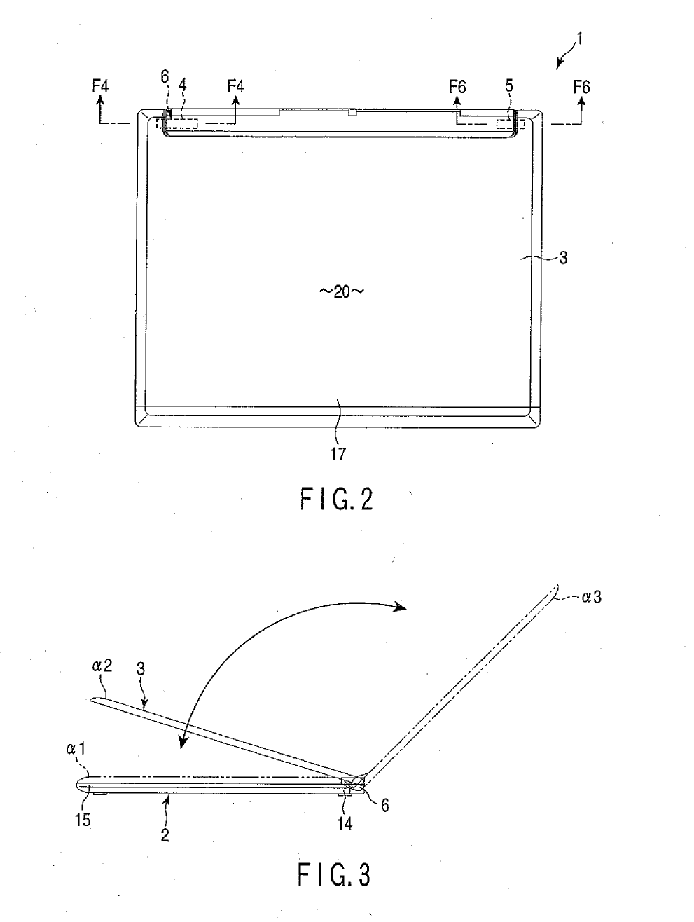

As shown in FIGS. 2 and 3, the first and second hinges 4 and 5 connect the display unit 3 to the rear end portion 14 of the main unit 2 so as to be rotatable with respect to the main unit 2. In this way, the display unit 3 can be rotated between a closed position where the display unit 3 falls and covers the main unit 2 from the upper side and an opened position where the display unit 3 rises with respect to the main unit 2.

Specifically, as shown in FIG. 3, the display unit 3 is rotated among a first angle α1 (for example, an open angle: 0 degree) at which the display unit 3 is laid on the main unit 2, a second angle α2 (for example, an open angle: 15 degrees) larger than the first angle α1, and a third angle α3 (for example, an open angle: 135 degrees) larger than the second angle α2. The term “open angle” means the angle formed between the desk surface on which the electronic apparatus 1 is placed and the display screen 18a. The third angle α3 is, for example, the maximum open angle of the display unit 3 (at which the display unit is not rotated any further). The second and third angles α2 and α3 are not particularly limited, but may be set to any values.

The second angle α2 is, for example, a boundary value for determining whether the user intends to use the electronic apparatus 1. That is, when the angle between the display unit 3 and the main unit 2 is less than the second angle α2 (that is, the angle is between the first and second angles α1 and α2), the display unit 3 is in a non-operating range in which the user may not use the electronic apparatus 1 and it is considered that the display unit 3 is at the time opening or closing. In the non-operating range, the first and second hinges 4 and 5 do not need to strongly support the display unit 3, and it is preferable that brake torque is small in order to facilitate the rotation of the display unit 3.

When the angle between the display unit 3 and the main unit 2 is more than the second angle α2 (that is, the angle is between the second and third angles α2 and α3), it is considered that the display unit 3 is in an operating range in which the user uses the electronic apparatus 1. In the used range, it is preferable that the first and second hinges 4 and 5 strongly support the display unit 3 such that the display unit 3 does not rattle.

In other words, the electronic apparatus 1 comprises a connecting portion 6 that comprises the first and second hinges 4 and 5, connects the display unit 3 and the main unit 2, and is rotated at the first angle α1 at which the display screen 18a of the display unit 3 covers the main unit 2 and the second angle α2 at which the display screen 18a of the display unit 3 is exposed.

A predetermined brake torque (first brake torque) acts on the first hinge 4 between the second and third angles α2 and α3, and a second brake torque less than the first brake torque acts on the first hinge 4 between the first and second angles α1 and α2, which will be described in detail below. In other words, the boundary where the first hinge 4 switches the first and second brake torques can be defined as the second angle α2.

For example, the first hinge 4 performs a drawing operation of drawing the display unit 3 to the main unit 2 between the first and second angles α1 and α2 when the display unit 3 is closed. The angle where the drawing operation starts can be defined as the second angle α2.

Next, the first hinge 4 will be described in detail.

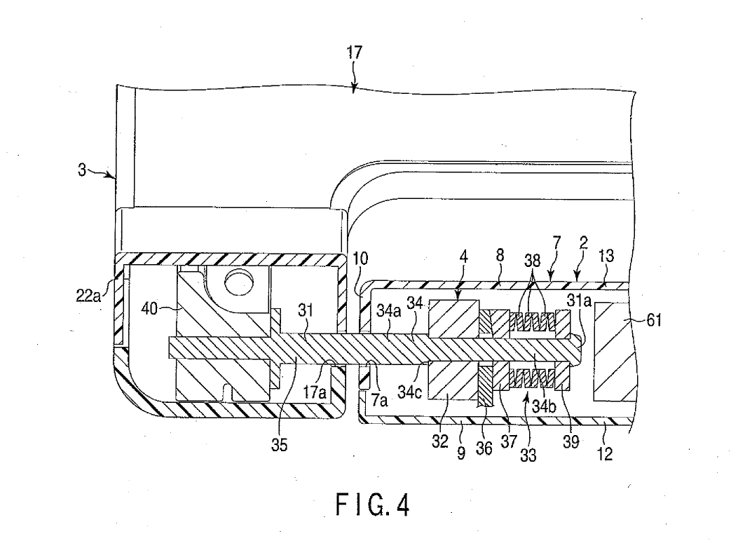

The first hinge 4 has a brake. As shown in FIG. 2, for example, the first hinge 4 is provided at the left end portion of the electronic apparatus 1. As shown in FIG. 4, the first hinge 4 comprises a shaft 31, a hinge metal plate 32, and a brake mechanism 33.

The shaft 31 extends in the substantially horizontal direction. The shaft 31 is inserted into through holes 7a and 17a respectively provided in the first and second housings 7 and 17 and extends from the first housing 7 into the second housing 17. The shaft 31 comprises a first portion 34 disposed in the first housing 7 and a second portion 35 disposed in the second housing 17.

The first portion 34 of the shaft 31 comprises a base portion 34a and a mounting portion 34b. The mounting portion 34b includes a flat portion provided in a part of the circumferential surface thereof (see a shaft 41 in FIG. 7). The hinge metal plate 32 and the brake mechanism 33 are penetrated by the mounting portion 34b.

A step portion 34c is formed between the base portion 34a and the mounting portion 34b. The hinge metal plate 32 is attached to the mounting portion 34b and is adjacent to the step portion 34c. The movement of the hinge metal plate 32 in the axial direction is regulated by the step portion 34c such that it is not taken off from the shaft 31 to the second portion 35. The hinge metal plate 32 faces the brake mechanism 33 and supports the brake mechanism 33 with one side thereof.

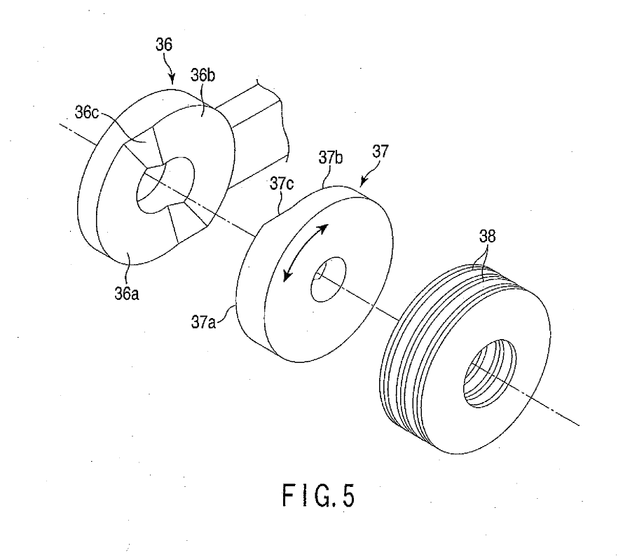

As shown in FIGS. 4 and 5, the brake mechanism 33 comprises a first brake member 36, a second brake member 37, disc springs 38, and a washer 39. The first brake member 36 is a hinge fixing portion and is fixed to the first housing 7. The entire first hinge 4 is supported by fixing the first brake member 36 to the first housing 7.

The first brake member 36 is not fixed to the shaft 31 and is not moved with the movement of the shaft 31. The shaft 31 can be rotated in the first brake member 36.

The second brake member 37 faces the first brake member 36. The second brake member 37 is fixed to the shaft 31 and is rotated with the rotation of the shaft 31. The disc springs 38 are opposite to the first brake member 36 with the second brake member 37 interposed therebetween. The disc springs 38 are supported by the washer 39. The washer 39 is supported by a caulked leading end portion 31a of the shaft 31 such that it is not taken off from the shaft 31.

The disc springs 38 are compressed between the second brake member 37 and the washer 39 and press the second brake member 37 to the first brake member 36. In this way, a frictional force is generated between the first and second brake members 36 and 37. The frictional force causes torque (brake torque) to act on the first hinge 4.

As shown in FIG. 5, the first brake member 36 comprises a first portion 36a and a second portion 36b. The second portion 36b is separated from the first portion 36a in the circumferential direction of the first brake member 36 and protrudes from the first portion 36a to the second brake member 37.

The first and second portions 36a and 36b are substantially flat. An inclined portion 36c that smoothly connects the first and second portions 36a and 36b is provided between the first and second portions 36a and 36b. The first brake member 36 is a cam having a protruding portion (second portion 36b) that protrudes in the axial direction.

The second brake member 37 comprises concave and convex portions that are engaged with convex and concave portions of the first brake member 36. The second brake member 37 comprises a third portion 37a and a fourth portion 37b. The third portion 37a is separated from the fourth portion 37b in the circumferential direction of the second brake member 37 and protrudes from the fourth portion 37b to the first brake member 36.

The third and fourth portions 37a and 37b are substantially flat. An inclined portion 37c that smoothly connects the third and fourth portions 37a and 37b is provided between the third and fourth portions 37a and 37b.

At the first angle α1, the third portion 37a faces the first portion 36a, and the fourth portion 37b faces the second portion 36b. In this case, the disc springs 38 are expanded to the maximum, and the brake torque is the minimum.

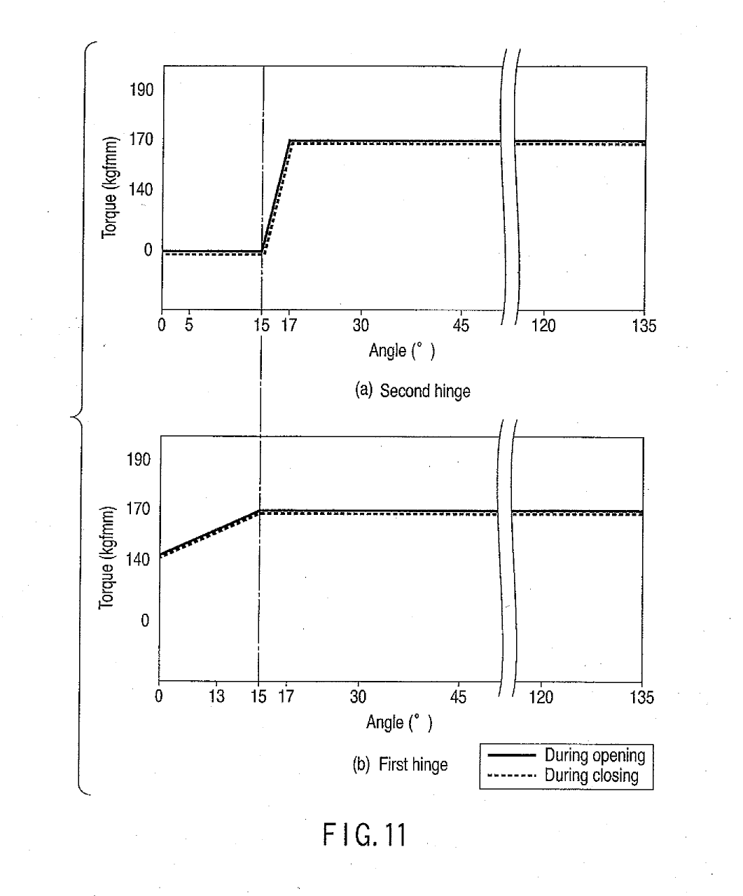

In this state, when the second brake member 37 is rotated with the rotation of the shaft 31, the end portion of the third portion 37a goes up the inclined portion 36c. In this way, the second brake member 37 is moved away from the first brake member 36 in the axial direction, and the disc springs 38 are compressed. Therefore, the brake torque is increased with the rotation of the second brake member 37 (see FIG. 11).

When the display unit 3 is rotated to the second angle α2, the third portion 37a goes up the inclined portion 36c and reaches the second portion 36b. Between the second and third angles α2 and α3, the third portion 37a is moved on the surface of the flat second portion 36b, and a predetermined brake torque (first brake torque) is generated.

On the other hand, during the closing of the display unit 3, at the second angle α2, when the end portion of the third portion 37a returns from the second portion 36b to the inclined portion 36c, the third portion 37a is pressed against the inclined portion 36c by the urging force of the disc springs 38. The third portion 37a pressed against the inclined portion 36c is moved to the first portion 36a along the inclined portion 36c.

In this way, torque for forcibly rotating the second brake member 37, that is, a drawing force (drawing function) for drawing the display unit 3 to the main unit 2 is generated between the first and second angles α1 and α2. The brake mechanism 33 is an example of a “drawing portion”.

As shown in FIG. 4, a bracket 40 is fixed to the second portion 35 of the shaft 31. The bracket 40 extends in the second housing 17 and is fixed to the second housing 17. That is, the bracket 40 supports the second housing 17.

Next, the second hinge 5 will be described in detail.

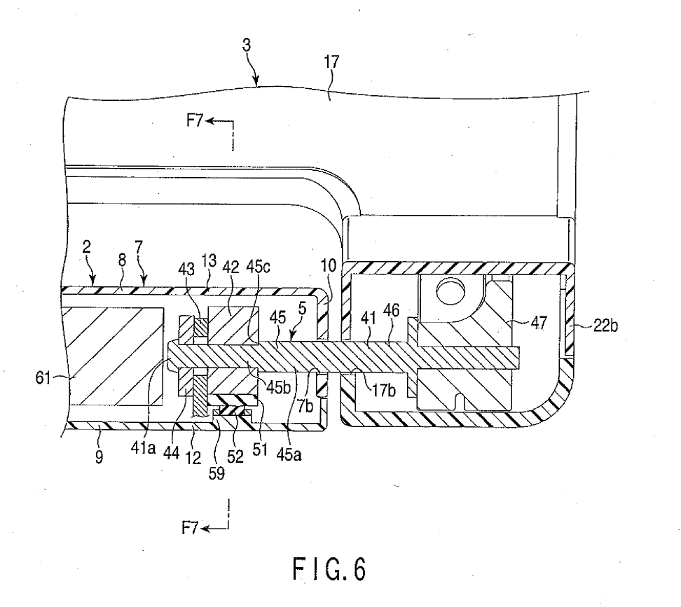

The second hinge 5 does not have a brake function like the first hinge 4. As shown in FIG. 2, for example, the second hinge 5 is provided at the right end portion of the electronic apparatus 1. The positions of the first and second hinges 4 and 5 may be reversed. As shown in FIG. 6, the second hinge 5 comprises a shaft 41, a hinge metal plate 42, a fixed portion 43, and a washer 44.

The shaft 41 extends in the substantially horizontal direction. The shaft 41 is inserted into through holes 7b and 17b respectively provided in the first and second housings 7 and 17 and extends from the first housing 7 into the second housing 17. The shaft 41 comprises a first portion 45 disposed in the first housing 7 and a second portion 46 disposed in the second housing 17.

The first portion 45 of the shaft 41 comprises a base portion 45a and a mounting portion 45b. The mounting portion 45b includes a flat portion provided in a part of the circumferential surface thereof (see FIG. 7). The hinge metal plate 42, the fixed portion 43, and the washer 44 are penetrated by the mounting portion 45b.

A step portion 45c is formed between the base portion 45a and the mounting portion 45b. The hinge metal plate 42 is attached to the mounting portion 45b and is adjacent to the step portion 45c. The movement of the hinge metal plate 42 in the axial direction is regulated by the step portion 45c such that it is not taken off from the shaft 41 to the second portion 46. The hinge metal plate 42 faces the fixed portion 43 and supports the fixed portion 43 with one side thereof.

The fixed portion 43 is fixed to the first housing 7. The entire second hinge 5 is supported by fixing the fixed portion 43 to the first housing 7. The fixed portion 43 is not fixed to the shaft 41, and is not moved with the rotation of the shaft 41. The shaft 41 can be rotated in the fixed portion 43.

The washer 44 is opposite to the hinge metal plate 42 with the fixed portion 43 interposed therebetween. The washer 44 is supported by a caulked leading end portion 41a of the shaft 41 such that it is not taken off from the shaft 41.

As shown in FIG. 6, the hinge metal plate 42 and the washer 44 are fixed to the shaft 41 and are rotated with the rotation of the shaft 41. Each of the shaft 41, the hinge metal plate 42, and the washer 44 is an example of a “rotating body”. The shaft 41, the hinge metal plate 42, and the washer 44 are rotated among the first angle α1, the second angle α2, and the third angle α3. The hinge metal plate 42 is made of a metal material and has, for example, a circular shape (see FIG. 7).

As shown in FIG. 6, a bracket 47 is fixed to the second portion 46 of the shaft 41. The bracket 47 extends in the second housing 17 and is fixed to the second housing 17. That is, the bracket 47 supports the second housing 17.

As shown in FIG. 7, first and second frictional portions 51 and 52 (external brake structures) are provided in the second hinge 5. The first frictional portion 51 is an example of a “frictional portion”. The second frictional portion 52 is an example of a “contact portion”. When the connecting portion 6 is rotated at the second angle α2, the first frictional portion 51 comes into contact with the second frictional portion 52 and torque acts on the connecting portion 6.

Specifically, for example, the first frictional portion 51 is provided on a circumferential surface 42a of the hinge metal plate 42 (rotating body). The hinge metal plate 42 comprises a concave portion 42b provided in a portion of the circumferential surface 42a thereof. An example of the first frictional portion 51 is a friction increasing member attached to the concave portion 42b of the hinge metal plate 42. The first frictional portion 51 protrudes from the circumferential surface 42a of the hinge metal plate 42 to the outside and forms a convex portion on the hinge metal plate 42.

The first frictional portion 51 is an elastically deformed member, such as felt or cushion (e.g., sponge rubber). The first frictional portion 51 is made of a material with frictional resistance larger than that of metal. In this embodiment, the first frictional portion 51 is provided in the hinge metal plate 42, but the invention is not limited thereto. The first frictional portion 51 may be provided in the “rotating body”. That is, the first frictional portion 51 may be provided in the shaft 41 or the washer 44.

The first frictional portion 51 is moved with the rotation of the hinge metal plate 42 (that is, the rotation of the display unit 3). Specifically, as shown in FIG. 8, the first frictional portion 51 is moved among a first position P1 corresponding to the first angle α1, a second position P2 corresponding to the second angle α2, and a third position P3 corresponding to the third angle α3.

As shown in FIG. 7, for example, the second frictional portion 52 is attached to the first housing 7. For example, the second frictional portion 52 is attached to the base member 12. The second frictional portion 52 may be attached to the cover member 13 or other portions in the first housing 7.

An example of the second frictional portion 52 is a friction increasing member. The second frictional portion 52 is an elastically deformed member, such as felt or cushion (e.g., sponge rubber). The second frictional portion 52 is made of a material with frictional resistance larger than that of metal. The second frictional portion 52 has, for example, a strip shape.

The first housing 7 comprises an arc-shaped base 59 along the circumferential surface 42a of the hinge metal plate 42. For example, the second frictional portion 52 is attached to the base 59 and has an arc shape, which corresponds to the shape of the base 59, along the circumferential surface 42a of the hinge metal plate 42 (that is, along the migration path of the first frictional portion 51). The second frictional portion 52 may be formed in an arc shape. The second frictional portion 52 may or may not come into contact with the circumferential surface 42a of the hinge metal plate 42.

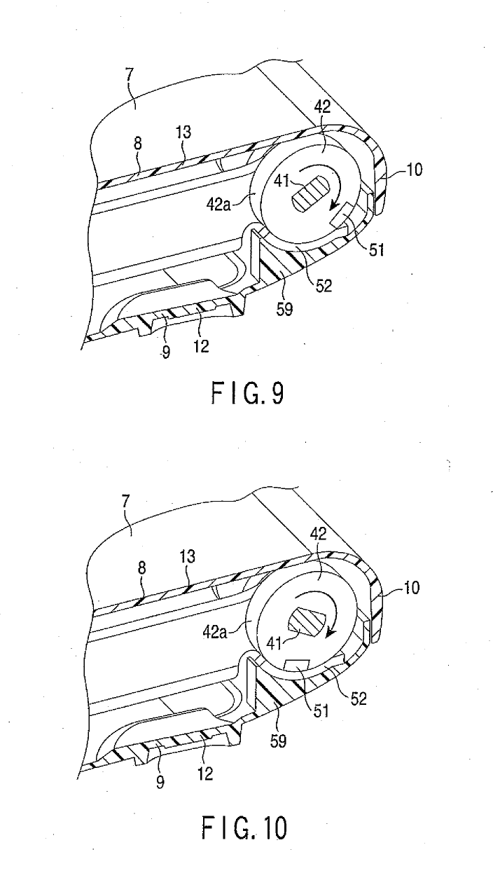

As shown in FIGS. 8 and 9, the second frictional portion 52 is not provided in a region that faces the first frictional portion 51 between the first and second angles α1 and α2 (between the first and second positions P1 and P2). The second frictional portion 52 faces a portion of the circumferential surface 42a of the hinge metal plate 42 away from the first frictional portion 51 between the first and second angles α1 and α2. Therefore, the second frictional portion 52 does not come into contact with the first frictional portion 51 between the first and second angles α1 and α2.

That is, no torque is generated from the second hinge 5 between the first and second angles α1 and α2. Even when the circumferential surface 42a of the hinge metal plate 42 comes into contact with the second frictional portion 52, the frictional resistance between the hinge metal plate 42 made of metal and the second frictional portion 52 is small, and the actual torque is substantially zero.

As shown in FIGS. 8 and 10, the second frictional portion 52 is provided so as to come into contact with the first frictional portion 51 reaching at the second position P2. In addition, the second frictional portion 52 is provided in the region that faces the first frictional portion 51 between the second and third angles α2 and α3 (between the second and third positions P2 and P3).

Therefore, the second frictional portion 52 faces and comes into contact with the first frictional portion 51 between the second and third angles α2 and α3. When the second frictional portion 52 comes into contact with the first frictional portion 51, for example, the frictional force is increased by the pressure contact between the felt and the felt, and a frictional force is generated on the basis of the contact between the first and second frictional portions 51 and 52. In this way, torque (brake torque) acts on the second hinge 5.

That is, a brake function is added from the outside to the second hinge 5. As shown in FIG. 11, the brake torque of the second hinge 5 is substantially equal to the first brake torque of the first hinge 4. That is, substantially the same torque acts on the left and right hinges 4 and 5.

When the display unit 3 is closed, the first and second frictional portions 51 and 52 do not contact each other at the second angle α2. That is, before the drawing portion of the first hinge 4 starts to draw the display unit 3, the second frictional portion 52 deviates from the first frictional portion 51 and the torque (frictional force) is removed.

Next, the function of the electronic apparatus 1 will be described.

As shown in FIG. 11, the first hinge 4 generates the minimum brake torque at the first angle α1. When the display unit 3 rises from the first angle α1, the third portion 37a of the second brake member 37 goes up the inclined portion 36c of the first brake member 36, and the brake torque is gradually increased up to the second angle α2.

Between the second and third angles α2 and α3, the third portion 37a of the second brake member 37 is moved on the flat surface of the second portion 36b of the first brake member 36. Therefore, a predetermined brake torque (first brake torque) is generated.

On the other hand, in the second hinge 5, the first and second frictional portions 51 and 52 do not contact each other between the first and second angles α1 and α2. Therefore, the brake torque is substantially zero. At the second angle α2, the contact between the first and second frictional portions 51 and 52 starts and the brake torque is gradually increased.

At a predetermine angle (offset angle, for example, an open angle: 17 degrees) offset from the second angle α2, the brake torque is the maximum. The maximum brake torque is maintained in the remainder of between the second and third angles α2 and α3. In this case, the first and second hinges 4 and 5 have substantially the same brake torque.

When the display unit 3 is closed, a predetermined first brake torque acts on the first hinge 4 between the second and third angles α2 and α3. When the display unit 3 reaches the second angle α2, the third portion 37a of the second brake member 37 goes into the inclined portion 36c of the first brake member 36, and the brake torque is gradually reduced. That is, between the first and second angles α1 and α2, the second brake torque less than the first brake torque is generated and the display unit 3 is drawn to the main unit 2 by the drawing operation.

On the other hand, when the display unit 3 is closed, a predetermined brake torque acts on the second hinge 5 between the second and third angles α2 and α3. In the second hinge 5, the contact between the first and second frictional portions 51 and 52 starts to be released from the offset angle slightly offset from the second angle α2, and the brake torque is gradually reduced. The brake torque is substantially zero at the second angle α2.

That is, in the second hinge 5, before the first hinge 4 starts the drawing operation, the brake torque is removed. Therefore, the drawing operation of the first hinge 4 is smoothly performed.

According to the electronic apparatus 1 having the above-mentioned structure, the hinge 4 with a brake function including, for example, the disc springs are provided at one end portion and the hinge without a brake function is provided at the other end portion. In this way, it is possible to reduce the number of parts. That is, the hinge without the brake function includes the first frictional portion 51 provided in the rotating body of the hinge and the second frictional portion 52 that comes into contact with the first frictional portion 51 and applies the brake torque to the hinge. Therefore, it is possible to ensure torque required to prevent the display unit 3 from being rattled.

Therefore, it is possible to use a hinge with a simple structure, instead of the hinge with the brake function that includes a large number of parts including, for example, the disc springs, and is expensive. As a result, it is possible to reduce the number of parts. The electronic apparatus 1 is advantageous in cost.

When the first and second frictional portions 51 and 52 do not contact each other between the first and second angles α1 and α2 and no torque is generated, unnecessary torque is not generated during the opening or closing of the display unit 3. Therefore, it is possible to smoothly rotate the display unit 3. That is, in this embodiment, torque is generated in the necessary range, and no torque is generated in the unnecessary range. Therefore, it is possible to achieve high operability.

When the second frictional portion 52 is incorporated into the hinge, a structure for supporting the second frictional portion 52 is needed, which results in an increase in the size of the hinge. In contrast, as in this embodiment, when the second frictional portion 52 is attached to the housing 7, the structure for supporting the second frictional portion 52 is not needed, which results in a reduction in the size of the hinge. Therefore, as shown in FIG. 6, it is possible to achieve a high-density mounting structure. For example, it is possible to ensure a large space for accommodating a battery 61 on the side of the second hinge 5.

During the closing of the display unit 3, when the second frictional portion 52 deviates from the first frictional portion 51 and the torque is removed before the first hinge 4 starts to draw the display unit 3, the first hinge 4 smoothly draws the display unit 3 without being affected by the torque of the second hinge 5. That is, the user can easily close the display unit 3. As a result, operability is improved.

When the first brake torque acts on the first hinge 4 between the second and third angles α2 and α3 and the second brake torque less than the first brake torque acts on the first hinge 4 between the first and second angles α1 and α2, the drawing operation is performed more smoothly.

When the second frictional portion 52 has an arc shape along the circumferential surface of the rotating body of the hinge, it is possible to contact the first and second frictional portions 51 and 52 only between the second and third angles α2 and α3 with a simple structure. When the first frictional portion 51 is a friction increasing member attached to the rotating body of the hinge is used, it is possible to achieve the function of the embodiment with a simpler structure.

Next, modifications of the embodiment will be described.

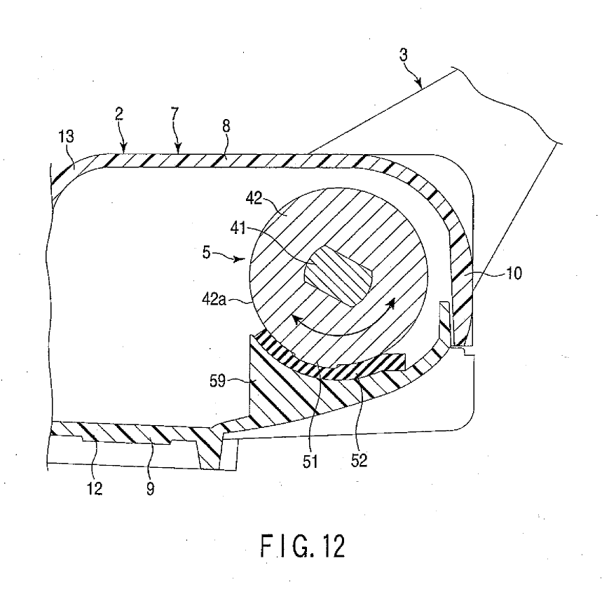

As shown in FIG. 12, the first frictional portion 51 may be a projection formed integrally with the “rotating body”. For example, the first frictional portion 51 is a portion of the hinge metal plate 42.

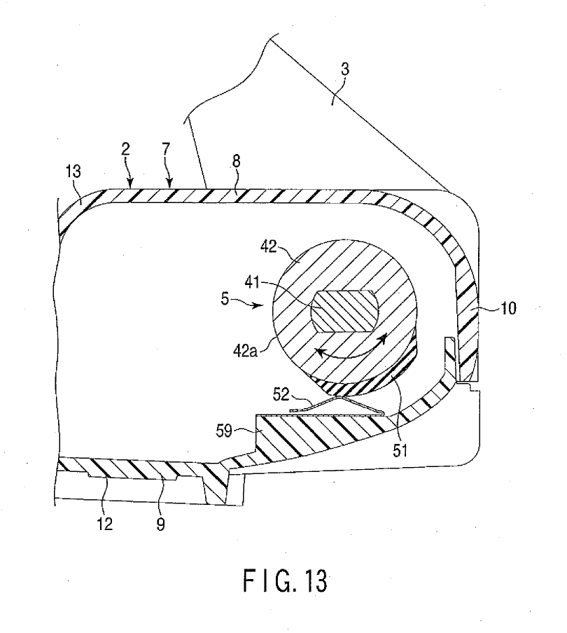

As shown in FIG. 13, the second frictional portion 52 may be a leaf spring that urges the first frictional portion 51. In this case, an example of the first frictional portion 51 is a friction increasing member provided in the “rotating body”. The first frictional portion 51 has an arc shape along the circumferential surface of the “rotating body” so as to come into contact with the second frictional portion 52 between the second and third angles α2 and α3.

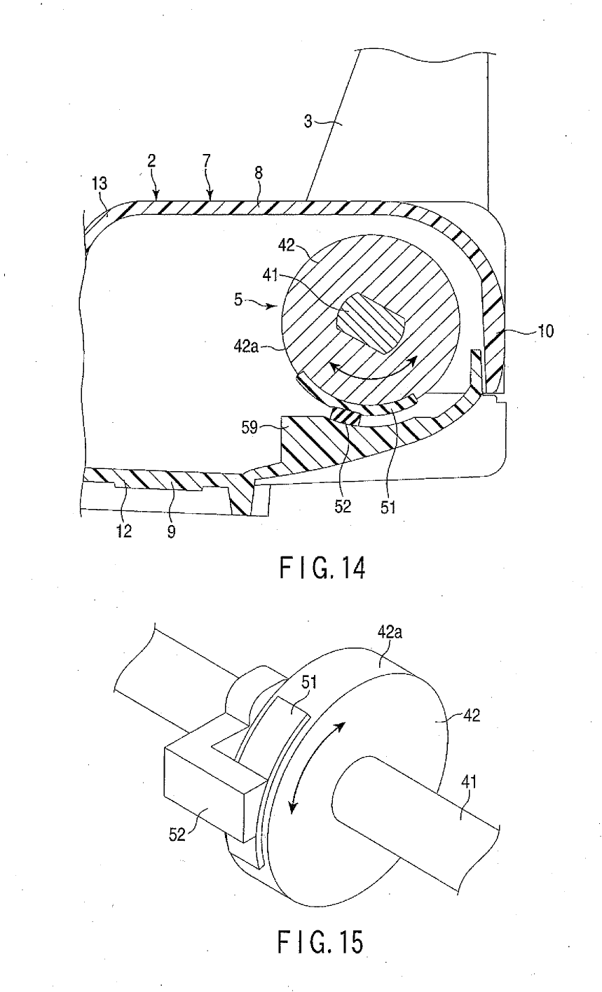

As shown in FIG. 14, the second frictional portion 52 may be a convex portion that protrudes toward the first frictional portion 51. In this case, for example, the first frictional portion 51 has an arc shape along the circumferential surface of the “rotating body” so as to come into contact with the second frictional portion 52 between the second and third angles α2 and α3.

As shown in FIG. 15, the second frictional portion 52 may be a portion of a hinge mechanism. That is, the second frictional portion 52 may be a part of a hinge assembly.

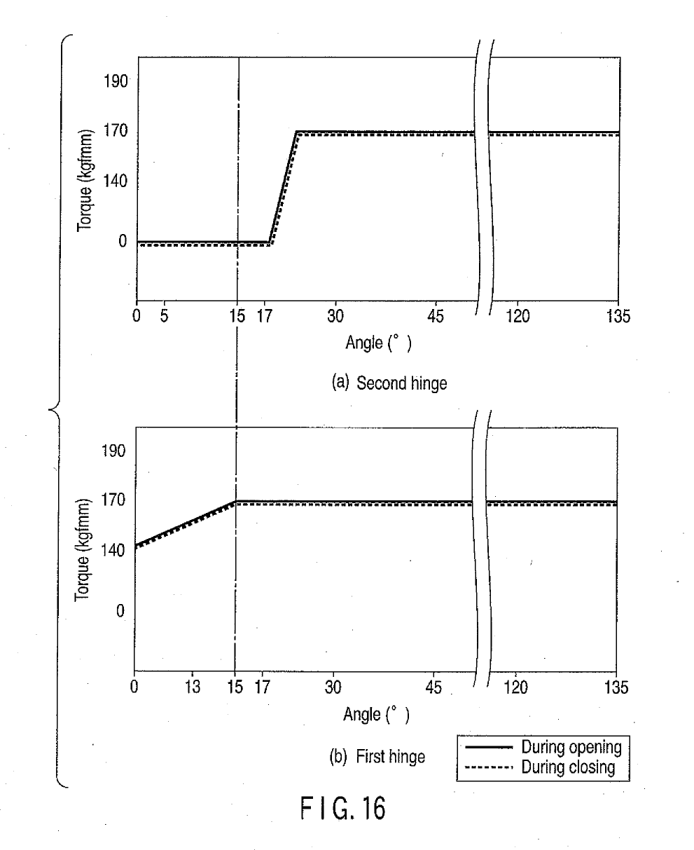

As shown in FIG. 16, the second hinge 5 may be provided such that the first and second frictional portions 51 and 52 contact each other from an angle larger than the second angle α2 and torque is generated. Specifically, for example, in the structure shown in FIG. 7, the first frictional portion 51 is arranged so as to deviate a little in the counterclockwise direction. According to this structure, it is possible to obtain the following effects.

When the user touches the display unit 3 in order to close the display unit 3, the housing 17 of the display unit 3 may be twisted. In this case, when the housing is bent such that the first hinge 4 is rotated earlier than the second hinge 5, the second hinge 5 is rotated later than the first hinge 4. Even when the first hinge 4 starts the drawing operation, the torque of the second hinge 5 is likely to remain.

In contrast, as shown in FIG. 16, when the display unit 3 is closed, the first and second frictional portions 51 and 52 are separated from each other before the display unit 3 reaches the second angle α2, and the torque is removed. In this case, even when the housing 17 is twisted, the torque of the second hinge 5 is removed when the first hinge 4 starts the drawing operation. In this way, it is possible to smoothly perform the drawing operation.

Although the electronic apparatus 1 according to the embodiment of the invention has been described above, the invention is not limited thereto. The invention is not limited to the above-described embodiment as it is, but various modifications and changes of the elements can be made without departing from the scope and spirit of the invention at the implementation stage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a main unit;
a display unit;
a first hinge pivotably attaching the display unit to the main unit and comprising a brake;
a second hinge pivotably attaching the display unit to the main unit, the second hinge comprising a rotating body comprising a first frictional portion and a surface away from the first frictional portion, wherein the second hinge is configured to rotate between a first angle at which the display unit is folded onto the main unit, a second angle larger than the first angle, and a third angle larger than the second angle; and
a second frictional portion configured to face the surface of the rotating body away from the first frictional portion between the first angle and the second angle and further configured to contact the first frictional portion and to generate a frictional force between the second angle and the third angle.

2. The electronic apparatus of claim 1,
wherein the main unit comprises a housing, and
the second frictional portion is attached to the housing.

3. The electronic apparatus of claim 1, wherein
the first hinge comprises a drawing portion configured to draw the display unit to the main unit between the first angle and the second angle when the display unit is closed, and
the second frictional portion is, configured to disengage from the first frictional portion before the drawing portion starts to draw the display unit.

4. The electronic apparatus of claim 1,
wherein the first hinge is configured to have a first brake torque between the second angle and the third angle, and to have a second brake torque less than the first brake torque between the first angle and the second angle.

5. The electronic apparatus of claim 1,
wherein the second frictional portion has an arc shape along the surface of the rotating body.

6. The electronic apparatus of claim 1,
wherein the first frictional portion is a friction increasing member attached to the rotating body.

7. The electronic apparatus of claim 1,
wherein the first frictional portion is a projection provided with the rotating body.

8. The electronic apparatus of claim 1,
wherein the second frictional portion is a leaf spring configured to press the first frictional portion.

9. An electronic apparatus comprising:
a main unit;
a display unit comprising a display screen;
a connecting portion comprising a first hinge comprising a brake and a second hinge comprising a frictional portion, the connecting portion attaching the display unit to the main unit and configured to rotate between a first angle at which the display screen of the display unit covers the main unit and a second angle at which the display screen of the display unit is exposed; and
a contact portion configured to contact with the frictional portion and to generate torque on the connecting portion when the connecting portion is rotated beyond the second angle.
